(19) United States
(12) Patent Application Publication
(10) Pub. No.: US 2026/0107640 A1
(43) Pub. Date: Apr. 16, 2026

(54) DISPLAY DEVICE AND ELECTRONIC APPARATUS INCLUDING THE SAME

(71) Applicant: Samsung Display Co., Ltd., Yongin-si (KR)

(72) Inventors: BOHWA KIM, Yongin-si (KR); KI YOUNG YEON, Yongin-si (KR); MIN-UK KIM, Yongin-si (KR)

(73) Assignee: Samsung Display Co., Ltd., Yongin-si (KR)

(21) Appl. No.: 19/346,985

(22) Filed: Oct. 1, 2025

(30) Foreign Application Priority Data
Oct. 10, 2024 (KR) 10-2024-0137927

(51) Int. Cl. H10K 59/122

(52) U.S. Cl. CPC H10K 59/122

(57) ABSTRACT

A display panel includes a base layer, a pixel definition layer on the base layer and including a first light emitting opening and a second light emitting opening, and a light emitting element layer including a first light emitting element overlapping the first light emitting opening and a second light emitting element overlapping the second light emitting opening. The pixel definition layer includes a valley pattern between the first light emitting opening and the second light emitting opening and recessed from an upper surface of the pixel definition layer in a thickness direction of the pixel definition layer, and the valley pattern includes a first valley pattern between the first light emitting opening and the second light emitting opening and disposed closer to the first light emitting opening than the second light emitting opening.

### CROSS-REFERENCE TO RELATED APPLICATION(S)

This application claims priority to and the benefits of Korean Patent Application No. 10-2024-0137927 under 35 U.S.C. § 119, filed Oct. 10, 2024, the entire contents of which are incorporated herein by reference.

### BACKGROUND

### 1. Technical Field

The disclosure relates to a display panel and an electronic apparatus including the display panel. More particularly, the disclosure relates to a display panel with improved display characteristics and an electronic apparatus including the display panel.

### 2. Description of the Related Art

An electronic apparatus, such as a smart phone, a tablet computer, a digital camera, a notebook computer, a navigation device, a television set, or the like, which provides a user with an image, includes a display panel to display the image.

The display panel includes red, green, and blue pixels to display colors, and a light emitting layer having the color of a corresponding pixel is formed in each pixel. In general, a light emitting layer is formed through a deposition method using a shadow mask, however, due to defects, such as, a sagging of the mask, etc., a process in which the light emitting layer and other organic layers are commonly formed over the pixels through an open mask is developed.

However, in the case where the organic layer is commonly formed, a lateral leakage current occurs due to the organic layer, which is commonly provided between adjacent pixels, resulting in color mixture and poor luminance between adjacent pixels.

The lateral leakage current is blocked by placing a valley pattern between pixels adjacent to each other. However, in case that a height or a slope of the valley pattern increases excessively, a thickness of the organic layer becomes non-uniform in an area adjacent to the pixel, and thus, an overshoot occurs due to accumulated surplus charges. In case that switching frames, the overshoot causes certain pixels to appear brighter than the set brightness, thereby causing image quality degradation.

### SUMMARY

The disclosure provides a display panel capable of reducing a charge imbalance in areas adjacent to pixels and preventing a lateral leakage current from occurring between adjacent pixels to prevent color mixture between adjacent pixels and improve poor image quality and an electronic apparatus including the display panel.

However, embodiments are not limited to those set forth herein. The above and other embodiments will become more apparent to one of ordinary skill in the art to which the disclosure pertains by referencing the detailed description of the disclosure given below.

Embodiments of the invention provide a display panel including a base layer, a pixel definition layer disposed on the base layer and including a first light emitting opening and a second light emitting opening, and a light emitting element layer including a first light emitting element overlapping the first light emitting opening and a second light emitting element overlapping the second light emitting opening. The pixel definition layer includes a valley pattern disposed between the first light emitting opening and the second light emitting opening and recessed from an upper surface of the pixel definition layer in a thickness direction of the pixel definition layer. The valley pattern includes a first valley pattern disposed between the first light emitting opening and the second light emitting opening and disposed closer to the first light emitting opening than the second light emitting opening. The first valley pattern includes a first-first side surface, a first-second side surface disposed closer to the second light emitting opening than the first-first side surface, and a lower surface disposed between the first-first side surface and the first-second side surface, and the first-first side surface has an inclination angle smaller than an inclination angle of the first-second side surface.

The inclination angle of the first-first side surface may be smaller than about 74 degrees, and the inclination angle of the first-second side surface may be greater than or equal to about 74 degrees and smaller than or equal to about 90 degrees.

The first light emitting element may include a first electrode partially exposed through the first light emitting opening, and a distance from a boundary between the first electrode and the first light emitting opening to the first-second side surface may be greater than or equal to about 8 micrometers.

The first valley pattern may have a depth smaller than or equal to about 650 nm.

The valley pattern may further include a second valley pattern disposed between the first light emitting opening and the second light emitting opening and disposed closer the second light emitting opening than the first light emitting opening. The second valley pattern may include a second-first side surface, a second-second side surface disposed closer to the first light emitting opening than the second-first side surface, and a lower surface disposed between the second-first side surface and the second-second side surface, and the second-first side surface may have an inclination angle smaller than an inclination angle of the second-second side surface.

The first valley pattern may include a first-first valley pattern and a first-second valley pattern, which are arranged to surround a portion of the first light emitting opening, and an area where the first-first valley pattern is spaced apart from the first-second valley pattern may face the second valley pattern.

The first light emitting element may include a first electrode partially exposed through the first light emitting opening, a first-first light emitting layer disposed on the first electrode, a charge generation layer disposed on the first-first light emitting layer, a second-first light emitting layer overlapping the first-first light emitting layer and disposed on the charge generation layer, and a second electrode disposed on the second-first light emitting layer and the charge generation layer.

The first-first light emitting layer and the second-first light emitting layer may emit lights having a same wavelength.

The second light emitting element may include a first electrode partially exposed through the second light emitting opening, a first-second light emitting layer disposed on the first electrode of the second light emitting element, the charge generation layer disposed on the first-second light emitting layer, a second-second light emitting layer overlapping the first-second light emitting layer and disposed on the charge generation layer, and the second electrode disposed on the second-second light emitting layer and the charge generation layer. The charge generation layer of the first light emitting element and the charge generation layer of the second light emitting element may have a single integrated shape, and the second electrode of the first light emitting element and the second electrode of the second light emitting element may have a single integrated shape.

The first-first light emitting layer and the second-first light emitting layer may emit lights having a same wavelength, and the first-first light emitting layer and the first-second light emitting layer may emit lights having different wavelengths from each other.

The charge generation layer may overlap the valley pattern, the charge generation layer may include an n-type charge generation layer and a p-type charge generation layer disposed on the n-type charge generation layer, and the n-type charge generation layer may be disconnected on the first-second side surface of the first valley pattern.

A portion of the charge generation layer, which overlaps the first-first side surface of the first valley pattern, may have a thickness greater than a thickness of a portion of the charge generation layer, which overlaps the first-second side surface of the first valley pattern.

The lower surface of the first valley pattern may include a first area and a second area disposed between the first area and the first-second side surface and recessed deeper than the first area.

The first valley pattern may include first to n-th valley patterns, where n may be an integer greater than 1, and the first to n-th valley patterns may be consecutively arranged from the first light emitting opening toward the second light emitting opening.

The first light emitting element may include a first electrode partially exposed through the first light emitting opening, and a distance from a boundary between the first electrode and the first light emitting opening to the first valley pattern may be greater than or equal to about 8 micrometers.

Embodiments provide a display panel including a base layer including a first light emitting area, a second light emitting area adjacent to the first light emitting area, and a non-light-emitting area adjacent to the first light emitting area and the second light emitting area, a pixel definition layer disposed on the base layer and including first and second light emitting openings to respectively overlap the first and second light emitting areas, and a light emitting element layer, at least a portion of which is disposed in the first and second light emitting openings. The pixel definition layer includes valley pattern overlapping the non-light-emitting area and recessed from an upper surface of the pixel definition layer in a thickness direction of the pixel definition layer, and the valley pattern includes a first valley pattern disposed closer to the first light emitting opening than the second light emitting opening and a second valley pattern disposed closer to the second light emitting opening than the first light emitting opening. The first valley pattern includes a first-first side surface surrounding a portion of the first light emitting area, a first-second side surface disposed closer to the second light emitting opening than the first-first side surface, and a lower surface disposed between the first-first side surface and the first-second side surface, and the first-first side surface has an inclination angle smaller than an inclination angle of the first-second side surface.

The light emitting element layer may include a first anode partially exposed through the first light emitting opening, a second anode partially exposed through the second light emitting opening, a first-first light emitting layer disposed on the first anode, a first-second light emitting layer disposed on the second anode, an organic layer commonly disposed on the first anode and the second anode, a second-first light emitting layer disposed on the first-first light emitting layer, a second-second light emitting layer disposed on the first-second light emitting layer, and a cathode commonly disposed on the second-first light emitting layer and the second-second light emitting layer.

Each of the first-first light emitting layer and the second-first light emitting layer may emit a first light, and each of the first-second light emitting layer and the second-second light emitting layer may emit a second light having a wavelength different from a wavelength of the first light.

A thickness of the organic layer on the first-first side surface may be greater than a thickness of the organic layer on the first-second side surface.

Embodiments provide an electronic apparatus including a display module, a window disposed on the display module, and an external case disposed under the display module. The display module includes a base layer, a pixel definition layer disposed on the base layer and includes a first light emitting opening and a second light emitting opening, and a light emitting element layer including a first light emitting element overlapping the first light emitting opening and a second light emitting element overlapping the second light emitting opening. The pixel definition layer includes valley pattern disposed between the first light emitting opening and the second light emitting opening and recessed from an upper surface of the pixel definition layer in a thickness direction of the pixel definition layer, and the valley pattern includes a first valley pattern disposed between the first light emitting opening and the second light emitting opening and disposed closer to the first light emitting opening than the second light emitting opening. The first valley pattern includes a first-first side surface, a first-second side surface disposed closer to the second light emitting opening than the first-first side surface, and a lower surface disposed between the first-first side surface and the first-second side surface, and the first-first side surface has an inclination angle smaller than an inclination angle of the first-second side surface.

According to the above, the valley pattern may include a side surface adjacent to an opening of the light emitting openings and another side surface adjacent to another opening of the light emitting openings and may have an asymmetric shape where the inclination of the one side surface is gentler than that of the other side surface. As the organic layer disposed on the one side surface of the valley pattern closer to the one opening may be formed more uniformly, the charge imbalance in the area adjacent to the one opening may be improved. Accordingly, the response speed and image quality characteristics of the display panel may be enhanced.

Additionally, the lateral leakage current is prevented by the other side surface of the valley pattern. As a result, the display panel provides a luminance corresponding to a grayscale value.

### BRIEF DESCRIPTION OF THE DRAWINGS

FIG. 1 is a schematic assembled perspective view of an electronic apparatus according to an embodiment;

FIG. 2 is an exploded schematic perspective view of an electronic apparatus according to an embodiment;

FIG. 3 is a schematic cross-sectional view of a display module according to an embodiment;

FIG. 4 is a schematic cross-sectional view of a portion of a display panel according to an embodiment;

FIG. 5A is an enlarged schematic plan view of a portion of a display panel according to an embodiment;

FIG. 5B is a schematic cross-sectional view of a display panel according to an embodiment;

FIG. 5C is an enlarged schematic cross-sectional view of a portion of a light emitting element according to an embodiment;

FIG. 6 is an enlarged schematic cross-sectional view of an area BB′ of FIG. 5B according to an embodiment; and

FIGS. 7, 8, 9A, and 9B are enlarged schematic cross-sectional views of portions of display panels according to embodiments.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z—axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within ±20%, ±10%, or ±5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described with reference to accompanying drawings.

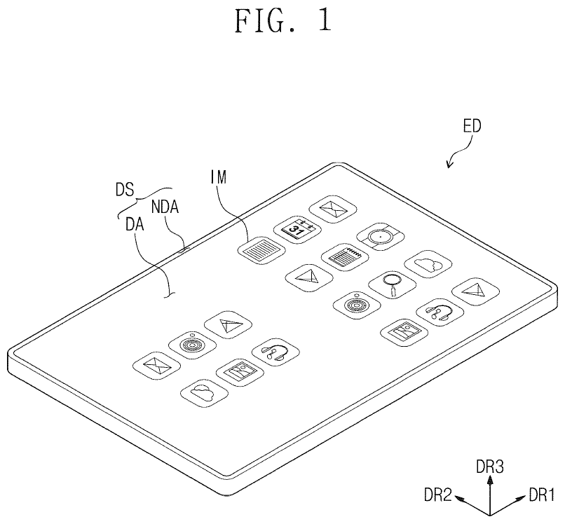

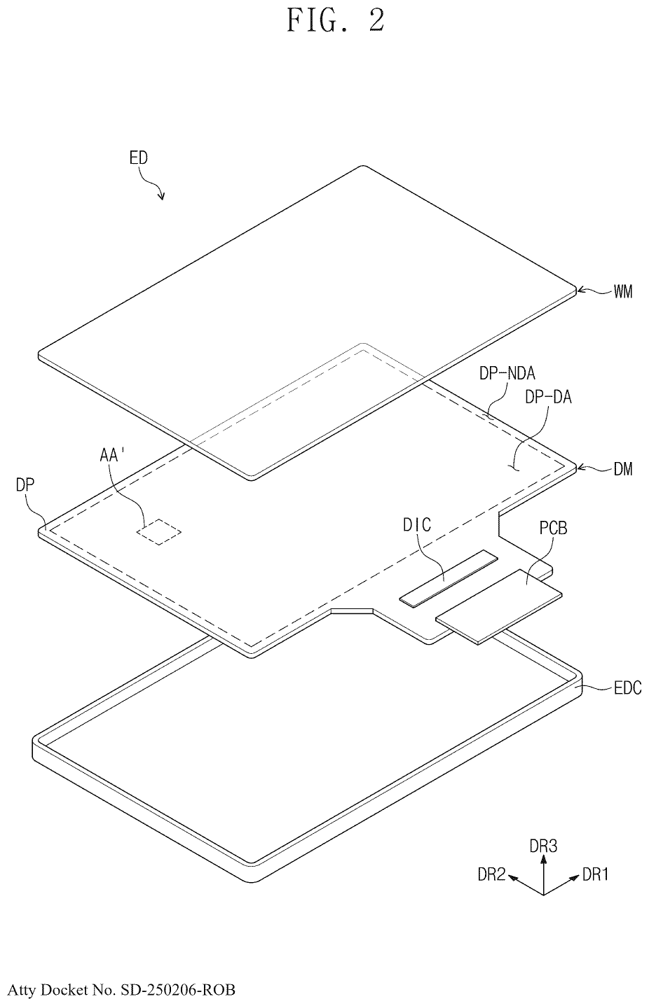

FIG. 1 is a schematic perspective view of an electronic device ED according to an embodiment. FIG. 2 is an exploded schematic perspective view of the electronic device ED according to an embodiment.

Referring to FIG. 1, the electronic device ED may be activated in response to electrical signals. The electronic device ED may display an image IM and may sense an external input. The electronic device ED may be implemented according to various embodiments. For example, the electronic device ED may be a tablet computer, a notebook computer, a computer, a smartphone, a television set, or the like. In the embodiment, the tablet computer is shown as the electronic device ED, however, the disclosure should not be limited thereto or thereby. The electronic device may be a smartphone or a large-sized display device, such as a notebook computer, a monitor, or a television set.

The electronic device ED may display the image IM through a display surface DS, which is substantially parallel to each of a first direction DR1 and a second direction DR2, toward a third direction DR3. The display surface DS through which the image IM is displayed may correspond to a front surface of the electronic device ED and a front surface of a window described later. The image IM may include a still image as well as a video. FIG. 1 shows application icons as a representative example of the image IM.

In the embodiment, front (or upper) and rear (or lower) surfaces of each member of the electronic device ED may be defined with respect to a direction in which the image IM is displayed. The front and rear surfaces may be opposite to each other in the third direction DR3, and a normal line direction of each of the front and rear surfaces may be substantially parallel to the third direction DR3. A separation distance in the third direction DR3 between the front surface and the rear surface may correspond to a thickness in the third direction DR3 of the electronic device ED. Directions indicated by the first, second, and third directions DR1, DR2, and DR3 may be relative to each other and may be changed to other directions. In the following descriptions, the expression “when viewed in a plane” or “in plan view” may mean a state of being viewed on the plane defined by the first direction DR1 and the second direction DR2.

The electronic device ED may sense a user input applied thereto from the outside. The user input may include various types of external inputs, such as a part of the user's body, light, heat, or pressure. The user input may be provided in various ways, and the electronic device ED may sense the user input applied to a side or rear surface of the electronic device ED according to its structure, however, the disclosure should not be limited thereto.

As shown in FIG. 2, the electronic device ED may include the window WM, a display module DM, and an external case EDC. In the embodiment, the window WM may be coupled to the external case EDC to form an exterior of the electronic device ED. In the embodiment, the external case EDC, the display module DM, and the window WM may be sequentially stacked in the third direction DR3.

The window WM may include an optically transparent material. The window WM may include an insulating panel. As an example, the window WM may include a glass, plastic, or combination thereof.

As described above, the front surface of the window WM may define the front surface of the electronic device ED.

The window WM may include a bezel area and a transmissive area. The transmissive area may be an optically transparent area. For example, the transmissive area may have a transmittance of about 90% or more with respect to a visible light.

The bezel area may have a light transmittance relatively lower than that of the transmissive area. The bezel area may define a shape of the transmissive area. The bezel area may be defined adjacent to the transmissive area and may surround the transmissive area. The bezel area may have a color. The bezel area may overlap a non-display area DP-NDA of a display panel DP described later. The bezel area may cover the non-display area DP-NDA of the display panel DP to prevent the non-display area DP-NDA from being viewed from the outside, however, this is an example. According to an embodiment, the bezel area may be omitted from the window WM.

The display module DM may include at least the display panel DP. FIG. 2 shows only the display panel DP among components of the display module DM, however, the display module DM may further include components disposed on and under the display panel DP. The detailed stack structure of the display module DM will be described later.

The display panel DP may include a display area DP-DA and the non-display area DP-NDA, which respectively correspond to a display area DA (refer to FIG. 1) and a non-display area NDA (refer to FIG. 1) of the electronic device ED. In the disclosure, the expression “an area/portion corresponds to another area/portion” means that “an area/portion overlaps another area/portion”, however, the “areas and portions” should not be limited to having the same size as each other. The display module DM may include a driving chip DIC disposed in the non-display area DP-NDA. The display module DM may further include a printed circuit board PCB coupled to the non-display area DP-NDA. The printed circuit board PCB may be electrically connected to pads arranged in the non-display area DP-NDA of the display panel DP by an anisotropic adhesive layer.

The driving chip DIC may include driving elements to drive pixels of the display panel DP. As an example, the driving chip DIC may include a data driving circuit. FIG. 2 shows a structure in which the driving chip DIC is mounted on the display panel DP, however, the disclosure should not be limited thereto or thereby. As an example, the driving chip DIC may be mounted on the printed circuit board PCB.

The external case EDC may accommodate the display module DM and may be coupled to the window WM. The external case EDC may protect components accommodated therein, such as the display module DM, from external impacts.

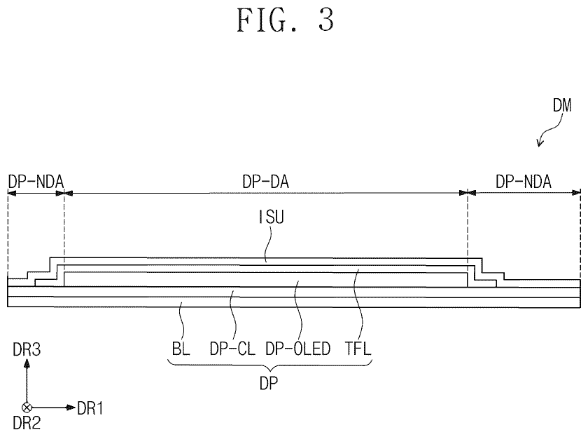

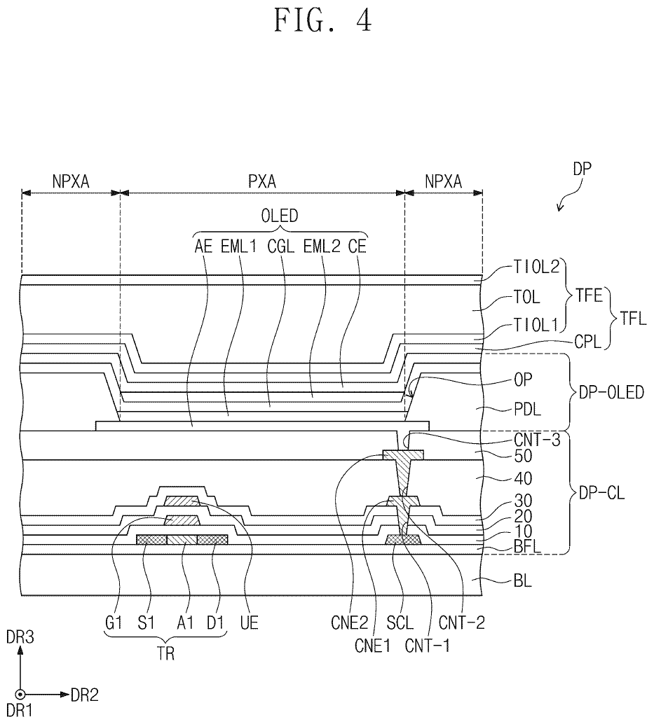

FIG. 3 is a schematic cross-sectional view of the display module DM according to an embodiment, and FIG. 4 is a schematic cross-sectional view of a portion of the display panel DP according to an embodiment. FIG. 4 shows a light emitting element OLED and a transistor TR included in a pixel of the display panel DP.

Referring to FIG. 3, the display module DM may include the display panel DP and an input sensing unit ISU. The display panel DP may have a configuration to generate the image IM (refer to FIG. 1). The image IM (refer to FIG. 1) generated by the display panel DP may be viewed from the outside by the user through the display area DA (refer to FIG. 1).

The display panel DP may be a light-emitting type display panel, however, it should not be limited thereto. For instance, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot, a quantum rod, or a micro-LED.

The input sensing unit ISU may be disposed on the display panel DP. The input sensing unit ISU may sense the external input received from the outside. The external input may include a variety of inputs provided from the outside of the electronic device ED (refer to FIG. 1). As an example, the external inputs may include a proximity input (e.g., hovering) applied when approaching close to or adjacent to the electronic device ED at a distance as well as a touch input by a part of the user's body (e.g., the user's hand). For example, the external inputs may be provided in the form of force, pressure, light, etc., and it should not be limited thereto.

The input sensing unit ISU may be formed on the display panel DP through successive processes. For example, the input sensing unit ISU may be disposed on (e.g., directly on) the display panel DP. In the following descriptions, the expression “a component A is disposed directly on a component B” means that no intervening elements are present between the component A and the component B. For example, a separate adhesive layer may not be disposed between the input sensing unit ISU and the display panel DP.

The display panel DP may include a base layer BL, a circuit element layer DP-CL disposed on the base layer BL, a display element layer DP-OLED disposed on the circuit element layer DP-CL, and an upper insulating layer TFL disposed on the display element layer DP-OLED.

The base layer BL may provide a base surface on which the circuit element layer DP-CL, the display element layer DP-OLED, and the upper insulating layer TFL are stacked. The base layer BL may be a rigid substrate or a flexible substrate that is bendable, foldable, or rollable. The base layer BL may be a glass substrate, a metal substrate, or a polymer substrate, however, it should not be limited thereto or thereby. According to an embodiment, the base layer BL may include an inorganic layer, an organic layer, or a composite material layer.

The base layer BL may have a multi-layer structure. For instance, the base layer BL may include a first synthetic resin layer, an inorganic layer having a single-layer structure or a multi-layer structure, and a second synthetic resin layer disposed on the inorganic layer having a single-layer structure or a multi-layer structure. Each of the first and second synthetic resin layers may include a polyimide-based resin, however, it should not be limited thereto.

The circuit element layer DP-CL may be disposed on the base layer BL. The circuit element layer DP-CL may include multiple insulating layers, multiple conductive layers, and a semiconductor layer. The conductive layers of the circuit element layer DP-CL may form signal lines or a control circuit of the pixel.

The display element layer DP-OLED may be disposed on the circuit element layer DP-CL. The display element layer DP-OLED may include light emitting elements OLED (refer to FIG. 4). The display element layer DP-OLED may include, for example, organic light emitting elements, however, this is an example. The display element layer DP-OLED may include inorganic light emitting elements, organic-inorganic light emitting elements, or a liquid crystal layer. In the disclosure, the display element layer DP-OLED may be referred to as a light emitting element layer.

The upper insulating layer TFL may include a capping layer and a thin film encapsulation layer described later. The upper insulating layer TFL may include an organic layer and multiple inorganic layers encapsulating the organic layer.

The upper insulating layer TFL may be disposed on the display element layer DP-OLED and may protect the display element layer DP-OLED from moisture, oxygen, and a foreign substance such as dust particles. The upper insulating layer TFL may encapsulate the display element layer DP-OLED to prevent moisture and oxygen from entering the display element layer DP-OLED. The upper insulating layer TFL may include at least one inorganic layer. The upper insulating layer TFL may include the organic layer and the inorganic layers encapsulating the organic layer. The upper insulating layer TFL may include a stack structure of inorganic layer/organic layer/inorganic layer.

The input sensing unit ISU may be disposed on the upper insulating layer TFL. The input sensing unit ISU may be formed on the upper insulating layer TFL through successive processes. The input sensing unit ISU may be disposed on (e.g., directly on) the display panel DP. For example, a separate adhesive member may not be disposed between the input sensing unit ISU and the display panel DP. The input sensing unit ISU may be disposed to be in contact with the inorganic layer disposed at an uppermost position of the upper insulating layer TFL.

For example, the display module DM according to an embodiment may further include a protective member disposed on a lower surface of the display panel DP and an anti-reflective member disposed on an upper surface of the input sensing unit ISU. The anti-reflective member may reduce a reflectance of the display module DM with respect to the external light. The anti-reflective member may be disposed on (e.g., directly on) the input sensing unit ISU through successive processes.

The anti-reflective member may include a light shielding pattern overlapping a reflective structure disposed under the anti-reflective member. The anti-reflective member may further include color filters. The color filters may be disposed between the light shielding pattern and may include a first color filter, a second color filter, and a third color filter, which correspond to a first color pixel, a second color pixel, and a third color pixel, respectively.

As shown in FIG. 3, the display panel DP may include the display area DP-DA and the non-display area DP-NDA in plan view. The display area DP-DA of the display panel DP may be an area in which the image IM is displayed, and the non-display area DP-NDA may be an area in which a driving circuit, a driving line, and the like are arranged. Light emitting elements of pixels may be arranged in the display area DP-DA. The display area DP-DA may overlap at least a portion of the transmissive area of the window WM (refer to FIG. 2), and the non-display area DP-NDA may be covered by the bezel area of the window WM.

Hereinafter, the circuit element layer DP-CL, the display element layer DP-OLED, and the upper insulating layer TFL will be described in detail with reference to FIG. 4.

Referring to FIG. 4, the circuit element layer DP-CL may include at least one insulating layer and a circuit element. The circuit element may include a signal line and a pixel driving circuit. The circuit element layer DP-CL may be formed by a coating process or a depositing process to form an insulating layer, a semiconductor layer, and a conductive layer and a photolithography process to pattern the insulating layer, the semiconductor layer, and the conductive layer.

The buffer layer BFL may include at least one inorganic layer. A semiconductor pattern may be disposed on the buffer layer BFL. The buffer layer BFL may increase an adhesive force between the base layer BL and the semiconductor pattern.

The semiconductor pattern may include polysilicon, however, it should not be limited thereto or thereby. The semiconductor pattern may include an amorphous silicon or metal oxide. FIG. 4 shows a portion of the semiconductor pattern, and the semiconductor pattern may be further disposed in other areas of the pixel in plan view. The semiconductor pattern may be arranged according to a specific rule over the pixels.

The semiconductor pattern may have different electrical properties according to whether the semiconductor pattern is doped or not. The semiconductor pattern may include a first region A1 with low doping concentration and low conductivity and second regions S1 and D1 with relatively high doping concentration and high conductivity. One second region S1 may be disposed adjacent to a side of the first region A1, and the other second region D1 may be disposed adjacent to another side of the first region A1. The second regions S1 and D1 may be doped with an N-type dopant or a P-type dopant. A P-type transistor may include a doped region doped with the P-type dopant. The first region A1 may be a non-doped region or may be doped at a concentration lower than the second regions S1 and D1.

The second regions S1 and D1 may substantially serve as an electrode or a signal line. The one second region S1 may correspond to a source of a transistor, and the other second region D1 may correspond to a drain of the transistor. FIG. 4 shows a portion of a connection signal line SCL formed of the semiconductor pattern. For example, the connection signal line SCL may be connected to the drain of the transistor TR in plan view.

A first insulating layer 10 may be disposed on the buffer layer BFL. The first insulating layer 10 may commonly overlap the pixels arranged in the display area DP-DA (refer to FIG. 3) and may cover the semiconductor pattern. The first insulating layer 10 may be an inorganic layer and/or an organic layer and may have a single-layer structure or a multi-layer structure. The first insulating layer 10 may include at least one of aluminum oxide, titanium oxide, silicon oxide, silicon oxynitride, zirconium oxide, and hafnium oxide. Not only the first insulating layer 10 but also an insulating layer of the circuit element layer DP-CL described later may be an inorganic layer and/or an organic layer and may have a single-layer structure or a multi-layer structure.

A gate G1 may be disposed on the first insulating layer 10. The gate G1 may be a portion of a metal pattern. The gate G1 may overlap the first region A1. The gate G1 may be used as a mask in a process of doping the semiconductor pattern.

A second insulating layer 20 may be disposed on the first insulating layer 10 and may cover the gate G1. The second insulating layer 20 may commonly overlap the pixels. An upper electrode UE may be disposed on the second insulating layer 20. The upper electrode UE may overlap the gate G1. The upper electrode UE may include multiple metal layers. In another example, the upper electrode UE may be omitted.

A third insulating layer 30 may be disposed on the second insulating layer 20 and may cover the upper electrode UE. A first connection electrode CNE1 may be disposed on the third insulating layer 30. The first connection electrode CNE1 may be connected to the connection signal line SCL via a contact hole CNT-1 defined through the first, second, and third insulating layers 10, 20, and 30.

A fourth insulating layer 40 may be disposed on the third insulating layer 30, and a fifth insulating layer 50 may be disposed on the fourth insulating layer 40. The fourth insulating layer 40 may be an organic layer. A second connection electrode CNE2 may be disposed on the fourth insulating layer 40. The second connection electrode CNE2 may be connected to the first connection electrode CNE1 via a contact hole CNT-2 defined through the fourth insulating layer 40.

The fifth insulating layer 50 may be disposed on the fourth insulating layer 40 and may cover the second connection electrode CNE2. The fifth insulating layer 50 may be an organic layer.

The light emitting element OLED may include a first electrode AE, a first light emitting layer EML1, a charge generation layer CGL, a second light emitting layer EML2, and the second electrode CE, which are sequentially stacked. The light emitting element OLED may be a light emitting element with a Tandem structure including the light emitting layers EML1 and EML2. Detailed descriptions on the Tandem structure will be described later.

The first electrode AE may be disposed on the circuit element layer DP-CL. The first electrode AE may be disposed on the fifth insulating layer 50 of the circuit element layer DP-CL. The first electrode AE may be connected to the second connection electrode CNE2 via a contact hole CNT-3 defined through the fifth insulating layer 50. Accordingly, the first electrode AE may be electrically connected to the connection signal line SCL through the first and second connection electrodes CNE1 and CNE2, and thus, the first electrode AE may be electrically connected to a corresponding circuit element. The first electrode AE may have a single-layer structure or a multi-layer structure.

The first electrode AE may be an anode or a cathode. For example, the first electrode AE may be a pixel electrode. The second electrode CE may be the cathode or the anode. The second electrode CE may be a common electrode. As an example, in case that the first electrode AE is the anode, the second electrode CE may be the cathode, and in case that the first electrode AE is the cathode, the second electrode CE may be anode.

The first and second light emitting layers EML1 and EML2 may emit lights having the same wavelength as each other. As an example, the light emitted from each of the first and second light emitting layers EML1 and EML2 may be a blue light, however, the disclosure should not be limited thereto or thereby. According to an embodiment, the lights emitted from the light emitting layers EML1 and EML2 may have different wavelength ranges from each other. As an example, at least one of the light emitting layers EML1 and EML2 may emit the blue light, and the other light emitting layer of the light emitting layers EML1 and EML2 may emit a green light. The light emitting element OLED including the light emitting layers EML1 and EML2 emitting the lights having different wavelength ranges from each other may emit a white light.

The charge generation layer CGL may be disposed between the first and second light emitting layers EML1 and EML2. In case that a voltage is applied to the charge generation layer CGL, the charge generation layer CGL may form a complex through an oxidation-reduction reaction, and thus may generate charges (e.g., electrons and holes). For example, the charge generation layer CGL may provide the generated charges to each of the light emitting layers EML1 and EML2. The charge generation layer CGL may double the efficiency of current generated in the light emitting layers EML1 and EML2 and may adjust a balance of the charges between the light emitting layers EML1 and EML2. The charge generation layer CGL may have a single integrated shape and may be commonly disposed over the pixels.

The second electrode CE may be disposed on the second light emitting layer EML2. The second electrode CE may have a single integrated shape and may be commonly disposed over the pixels.

The display element layer DP-OLED may include a pixel definition layer PDL disposed on the circuit element layer DP-CL. A light emitting opening OP may be defined through the pixel definition layer PDL, and at least a portion of the first electrode AE may be exposed through the light emitting opening OP of the pixel definition layer PDL. According to an embodiment, the pixel definition layer PDL may cover an edge portion of the first electrode AE.

The display area DP-DA (refer to FIG. 3) may include a light emitting area PXA and a non-light-emitting area NPXA adjacent to the light emitting area PXA. The non-light-emitting area NPXA may surround the light emitting area PXA. In the embodiment, the light emitting area PXA may be defined to correspond to the portion of the first electrode AE, which is exposed through the light emitting opening OP. In the disclosure, the light emitting area PXA may be referred to as a pixel area, and the non-light-emitting area NPXA may be referred to as a non-pixel area.

The pixel definition layer PDL may have a single-layer structure or a multi-layer structure. The pixel definition layer PDL may include a polymer resin. As an example, the pixel definition layer PDL may include a polyacrylate-based resin or a polyimide-based resin. For example, the pixel definition layer PDL may further include an inorganic material in addition to the polymer resin. The pixel definition layer PDL may include a light absorbing material, a black pigment, or a black dye. The pixel definition layer PDL including the black pigment or the black dye may be implemented as a black pixel definition layer. In case that the pixel definition layer PDL is formed, a carbon black may be used as the black pigment or the black dye, however, the embodiment should not be limited thereto or thereby.

For example, the pixel definition layer PDL may include the inorganic material. As an example, the pixel definition layer PDL may include inorganic material such as silicon nitride (SiNₓ), silicon oxide (SiOₓ), or silicon oxynitride (SiOₓN_{y}).

Referring to FIG. 4, the upper insulating layer TFL may be disposed on the display element layer DP-OLED and may include thin films. According to an embodiment, the upper insulating layer TFL may include the capping layer CPL and the encapsulation layer TFE disposed on the capping layer CPL. The capping layer CPL may be disposed on the second electrode CE and may be in contact with the second electrode CE. The capping layer CPL may include an organic material.

The encapsulation layer TFE may include a first inorganic encapsulation layer TIOL1, an organic encapsulation layer TOL disposed on the first inorganic encapsulation layer TIOL1, and a second inorganic encapsulation layer TIOL2 disposed on the organic encapsulation layer TOL. The first inorganic encapsulation layer TIOL1 and the second inorganic encapsulation layer TIOL2 may protect the display element layer DP-OLED from moisture and oxygen, and the organic encapsulation layer TOL may protect the display element layer DP-OLED from a foreign substance such as dust particles.

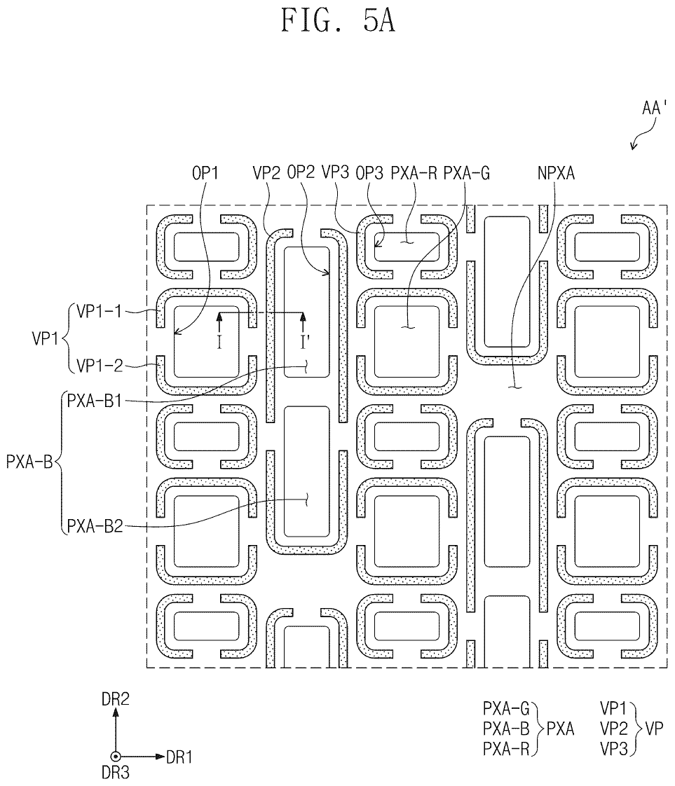

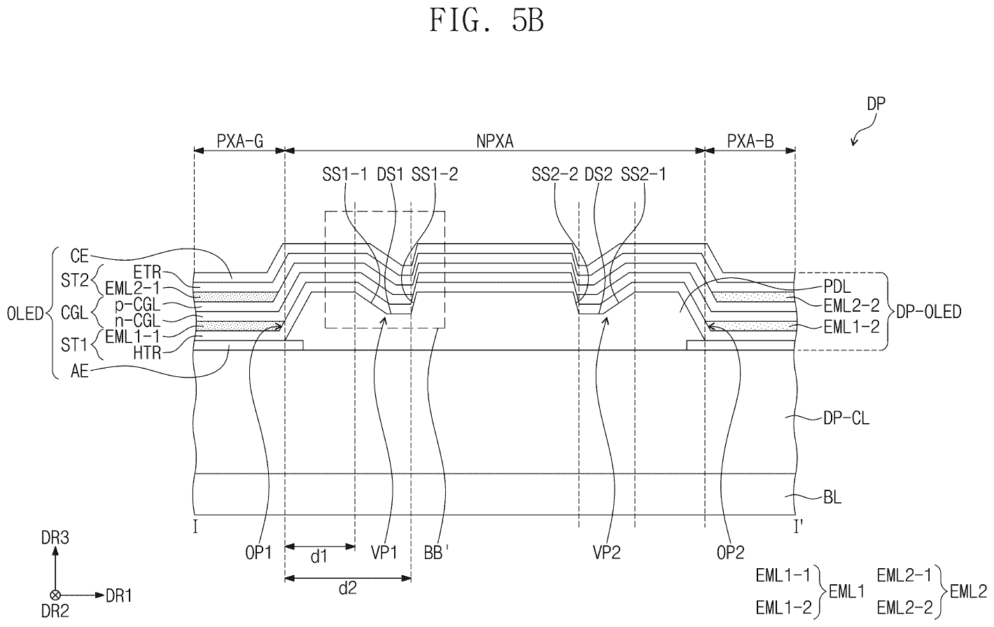

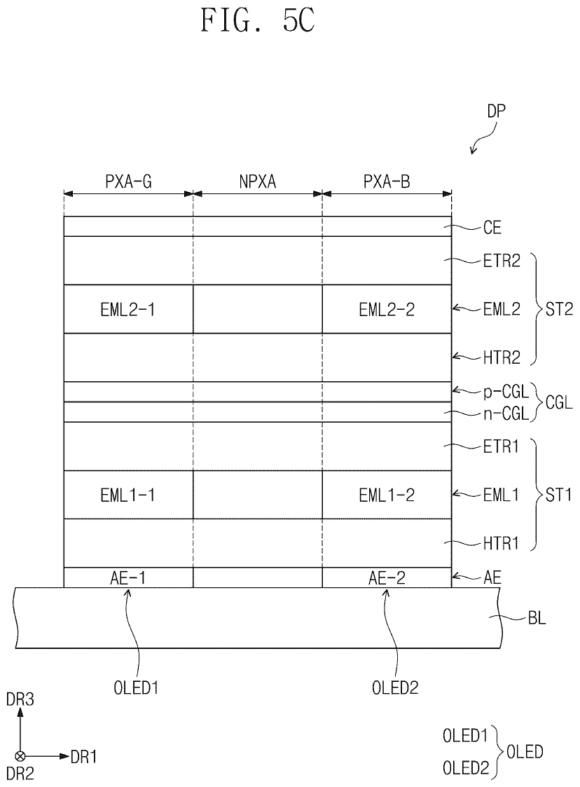

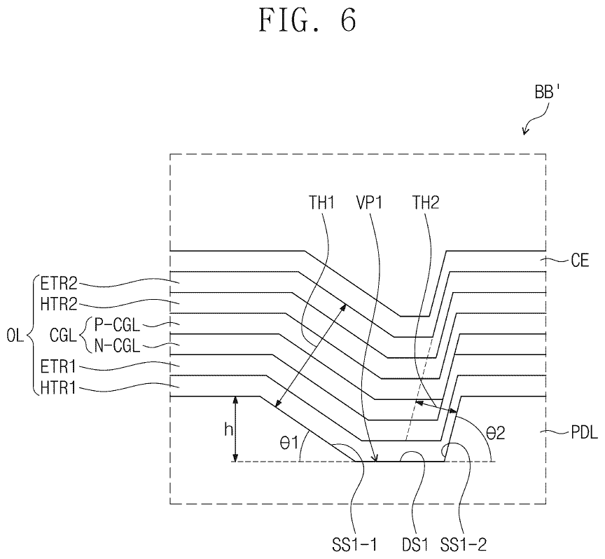

FIG. 5A is an enlarged schematic plan view of a portion of the display panel DP (refer to FIG. 2) according to an embodiment, FIG. 5B is a schematic cross-sectional view of the display panel DP according to an embodiment, and FIG. 5C is an enlarged schematic cross-sectional view of a portion of the light emitting element OLED according to an embodiment. FIG. 6 is an enlarged schematic cross-sectional view of an area BB′ of FIG. 5B according to an embodiment.

FIG. 5A is an enlarged schematic plan view showing an arrangement of the pixels and a valley pattern defined adjacent to the pixels in an area AA′ of FIG. 2.

Referring to FIGS. 2 and 5A, the display area DP-DA of the display panel DP may include light emitting areas PXA-G, PXA-B, and PXA-R and a non-light-emitting area NPXA surrounding the light emitting areas PXA-G, PXA-B, and PXA-R. The light emitting areas PXA-G, PXA-B, and PXA-R may include a first light emitting area PXA-G, a second light emitting area PXA-B, and a third light emitting area PXA-R. The first light emitting area PXA-G, the second light emitting area PXA-B, and the third light emitting area PXA-R may display lights of different wavelengths. The first light emitting area PXA-G may display a first light of a green wavelength, the second light emitting area PXA-B may display a second light of a blue wavelength, and the third light emitting area PXA-R may display a third light of a red wavelength.

As shown in FIG. 5A, the first light emitting areas PXA-G may be alternately arranged with the third light emitting areas PXA-R in the second direction DR2 to form a first light emitting group, and the second light emitting areas PXA-B may be arranged in the second direction DR2 to form a second light emitting group. In the embodiment, the second light emitting group may include sub-light emitting groups, and each of the sub-light emitting groups may include two second light emitting areas PXA-B. The two second light emitting areas PXA-B included in one sub-pixel group may be referred to as a second-first light emitting area PXA-B1 and a second-second light emitting area PXA-B2, respectively.

Each of the first light emitting group including the first and third light emitting areas PXA-G and PXA-R and the second light emitting group including the second-first and second-second light emitting areas PXA-B1 and PXA-B2 may be provided in plural, and the first light emitting groups may be alternately arranged with the second light emitting groups in the first direction DR1.

The light emitting areas PXA-G, PXA-B, and PXA-R may be distinguished from each other by the pixel definition layer PDL (refer to FIG. 4). The non-light-emitting area NPXA may correspond to areas between the light emitting areas PXA-G, PXA-B, and PXA-R and may correspond to the pixel definition layer PDL (refer to FIG. 4).

In the disclosure, each of the light emitting areas PXA-G, PXA-B, and PXA-R may correspond to the pixel. The light emitting areas PXA-G, PXA-B, and PXA-R may be distinguished from each other to correspond to the light emitting opening OP (refer to FIG. 4) defined through the pixel definition layer PDL (refer to FIG. 4).

The light emitting areas PXA-G, PXA-B, and PXA-R may have different sizes from each other according to wavelengths of the lights emitted from the light emitting areas PXA-G, PXA-B, and PXA-R. As an example, as shown in FIG. 5A, the second light emitting area PXA-B emitting the second light may have the largest size, and the third light emitting area PXA-R emitting the third light may have the smallest size, however, the disclosure should not be limited thereto or thereby. According to an embodiment, the light emitting areas PXA-G, PXA-B, and PXA-R may have the same size as each other, or the light emitting areas PXA-G, PXA-B, and PXA-R may be defined with an area ratio different from that shown in FIG. 5A. According to an embodiment, the light emitting areas PXA-G, PXA-B, and PXA-R may emit lights of other colors other than the green wavelength light, the blue wavelength light, and the red wavelength light.

Each of the light emitting areas PXA-G, PXA-B, and PXA-R may have a rectangular shape with rounded corners in plan view. Each of the first light emitting area PXA-G and the second light emitting area PXA-B may have the rectangular shape with long sides extending in the second direction DR2 and short sides extending in the first direction DR1, and corners where adjacent long sides and short sides are connected may have a rounded shape. The third light emitting area PXA-R may have a rectangular shape with long sides extending in the first direction DR1 and short sides extending in the second direction DR2, and corners where adjacent long sides and short sides are connected may have a rounded shape.

As shown in FIGS. 5A and 5B, the base layer BL may include the first light emitting area PXA-G, the second light emitting area PXA-B adjacent to the first light emitting area PXA-G, and the non-light-emitting area NPXA adjacent to the first light emitting area PXA-G and the second light emitting area PXA-B. A first light emitting opening OP1 corresponding to the first light emitting area PXA-G and a second light emitting opening OP2 corresponding to the second light emitting area PXA-B may be defined through the pixel definition layer PDL disposed on the base layer BL.

For example, valley patterns VP1, VP2, and VP3 may be defined to overlap the non-light-emitting area NPXA adjacent to each of the light emitting areas PXA-G, PXA-B, and PXA-R and surrounding a portion of each of the light emitting areas PXA-G, PXA-B, and PXA-R in plan view.

The valley patterns VP1, VP2, and VP3 may be defined in the pixel definition layer PDL (refer to FIG. 4). The valley patterns VP1, VP2, and VP3 may have a shape recessed from an upper surface of the pixel definition layer PDL (refer to FIG. 4) along a thickness direction of the pixel definition layer PDL (refer to FIG. 4) when viewed in the cross-section. The shape of the valley patterns VP1, VP2, and VP3 in the cross-section will be described in detail later.

The valley patterns VP1, VP2, and VP3 may include a first valley pattern VP1 surrounding the portion of the first light emitting area PXA-G, a second valley pattern VP2 surrounding the portion of the second light emitting area PXA-B, and a third valley pattern VP3 surrounding the portion of the third light emitting area PXA-R. Each of the first valley pattern VP1, the second valley pattern VP2, and the third valley pattern VP3 may surround the portion of each of the first light emitting area PXA-G, the second light emitting area PXA-B, and the third light emitting area PXA-R and may not surround the other portion of each of the first light emitting area PXA-G, the second light emitting area PXA-B, and the third light emitting area PXA-R.

The first valley pattern VP1 may include a first-first valley pattern VP1-1 and a first-second valley pattern VP1-2, which are arranged to surround the portion of the first light emitting area PXA-G. The first-first valley pattern VP1-1 and the first-second valley pattern VP1-2 may be spaced apart from each other. As shown in FIG. 5A, the first-first valley pattern VP1-1 and the first-second valley pattern VP1-2 may be spaced apart from each other in the second direction DR2.

In plan view, a portion where the first-first valley pattern VP1-1 and the first-second valley pattern VP1-2 are spaced apart from each other may face the second valley pattern VP2 adjacent to the portion in the first direction DR1. According to an embodiment, in plan view, the second valley pattern VP2 may include spaced apart portions, where one spaced apart portion of the second valley pattern VP2 may face the third valley pattern VP3 adjacent the portion in the first direction DR1 and another spaced apart portion of the second valley pattern VP2 may face another second valley pattern VP2 adjacent the portion in the second direction DR2. Similarly, in plan view, the third valley pattern VP3 may include spaced part potions, where the spaced apart portion faces the first valley pattern VP1 in the second direction DR2.

In the display panel according to the embodiment, the valley patterns VP1, VP2, and VP3 surrounding the portion of each of the light emitting areas PXA-G, PXA-B, and PXA-R may be defined to prevent a lateral leakage current from occurring between the pixels adjacent to each other. In the disclosure, the lateral leakage current may refer to a current that flows in a direction other than the third direction DR3, which is the stacking direction of the light emitting element, e.g., the direction in which the image IM is displayed. The lateral leakage current may refer to a current flowing in a direction parallel to the plane defined by the first direction DR1 and the second direction DR2.

Referring to FIGS. 5A and 5B, as the valley patterns VP1, VP2, and VP3 recessed in the thickness direction of the pixel definition layer PDL are defined in the display panel DP according to the disclosure, the occurrence of the lateral leakage current may be prevented between the light emitting areas PXA-G, PXA-B, and PXA-R. Accordingly, the color mixture between the pixels adjacent to each other may be prevented, and the luminance deterioration may be prevented.

As shown in FIGS. 5A and 5B, the first valley pattern VP1 disposed between the first light emitting opening OP1 and the second light emitting opening OP2 may be disposed closer to the first light emitting opening OP1 than the second light emitting opening OP2. For example, the first valley pattern VP1 may be disposed closer to the first light emitting area PXA-G than the second light emitting area PXA-B. For example, the first valley pattern VP1 disposed between the first light emitting opening OP1 and a third light emitting opening OP3 may be disposed closer to the first light emitting opening OP1 than the third light emitting opening OP3.

The second valley pattern VP2 disposed between the second light emitting opening OP2 and the first light emitting opening OP1 may be disposed closer to the second light emitting opening OP2 than the first light emitting opening OP1, and the second valley pattern VP2 disposed between the second light emitting opening OP2 and the third light emitting opening OP3 may be disposed closer to the second light emitting opening OP2 than the third light emitting opening OP3. For example, the second valley pattern VP2 may be disposed closer to the second light emitting area PXA-B than the first light emitting area PXA-G. Similarly, the third valley pattern VP3 disposed between the third light emitting opening OP3 and the first light emitting opening OP1 may be disposed closer to the third light emitting opening OP3 than the first light emitting opening OP1, and the third valley pattern VP3 disposed between the third light emitting opening OP3 and the second light emitting opening OP2 may be disposed closer to the third light emitting opening OP3 than the second light emitting opening OP2.

FIG. 5B is an enlarged schematic cross-sectional view of the portion of the display panel DP taken along a line I-I′ of FIG. 5A according to an embodiment, and FIG. 5C is a schematic cross-sectional view of the portion of the light emitting element OLED. In FIGS. 5B and 5C, the same/similar reference numerals denote the same/similar elements in FIGS. 1 to 5A, and thus, detailed descriptions of the same/similar elements will be omitted.

Referring to FIGS. 5A, 5B, and 5C, the display panel DP may include the base layer BL, the circuit element layer DP-CL disposed on the base layer BL, and the display element layer DP-OLED. For example, the upper insulating layer TFL (refer to FIG. 4) may be further disposed on the display element layer DP-OLED.

The light emitting element OLED disposed on the circuit element layer DP-CL may include the first electrode AE, a first light emitting stack ST1, the charge generation layer CGL, a second light emitting stack ST2, and the second electrode CE, which are sequentially stacked in the third direction DR3. In FIG. 5B, the first light emitting stack ST1 may include the first light emitting layer EML1 and a hole control layer HTR disposed between the first light emitting layer EML1 and the first electrode AE, and the second light emitting stack ST2 may include the second light emitting layer EML2 and an electron control layer ETR disposed between the second light emitting layer EML2 and the second electrode CE. For example, the electron control layer ETR may be further disposed between the first light emitting layer EML1 and the charge generation layer CGL, and the hole control layer HTR may be further disposed between the charge generation layer CGL and the second light emitting layer EML2.

The charge generation layer CGL may include multiple layers of an n-type charge generation layer n-CGL and a p-type charge generation layer p-CGL, which are attached to each other. The n-type charge generation layer n-CGL may be a charge generation layer that provides electrons to the first light emitting layer EML1, which is adjacent to the n-type charge generation layer n-CGL. The n-type charge generation layer n-CGL may be a layer formed by doping a base material with an n-dopant. The p-type charge generation layer p-CGL may be a charge generation layer that provides holes to the second light emitting layer EML2, which is adjacent to the p-type charge generation layer p-CGL. The p-type charge generation layer p-CGL may be a layer formed by doping a base material with a p-dopant.

Referring to FIGS. 5A, 5B, and 5C, the first light emitting opening OP1 corresponding to the first light emitting area PXA-G and the second light emitting opening OP2 corresponding to the second light emitting area PXA-B may be defined through the pixel definition layer PDL. For example, referring to FIG. 5A, the third light emitting opening OP3 corresponding to the third light emitting area PXA-R may be defined.

The light emitting element OLED may include a first light emitting element OLED1 corresponding to the first light emitting opening OP1 and a second light emitting element OLED2 corresponding to the second light emitting opening OP2. The second light emitting element OLED2 may have the same stack structure as the first light emitting element OLED1 except for light emitting layers EML1-1 and EML2-1 of the first light emitting element OLED1.

The first light emitting element OLED1 may include a first-first electrode AE-1 partially exposed through the first light emitting opening OP1, the first light emitting stack ST1 disposed on the first-first electrode AE-1, the charge generation layer CGL, the second light emitting stack ST2, and the second electrode CE, which are sequentially stacked on the base layer BL along the third direction DR3.

The first light emitting stack ST1 of the first light emitting element OLED1 may include a first hole control layer HTR1, a first-first light emitting layer EML1-1, and a first electron control layer ETR1. The second light emitting stack ST2 of the first light emitting element OLED1 may include a second hole control layer HTR2, a second-first light emitting layer EML2-1, and a second electron control layer ETR2.

According to an embodiment, the first-first light emitting layer EML1-1 and the second-first light emitting layer EML2-1 may emit lights having the same wavelength as each other. As an example, the light emitted from each of the first-first light emitting layer EML1-1 and the second-first light emitting layer EML2-1 may be the green light.

The second light emitting element OLED2 may include a first-second electrode AE-2 partially exposed through the second light emitting opening OP2, the first light emitting stack ST1 disposed on the first-second electrode AE-2, the charge generation layer CGL, the second light emitting stack ST2, and the second electrode CE, which are sequentially stacked on the base layer BL along the third direction DR3.

The first-first electrode AE-1 partially exposed through the first light emitting opening OP1 may be referred to as a first anode, and the first-second electrode AE-2 partially exposed through the second light emitting opening OP2, may be referred to as a second anode.

The first light emitting stack ST1 of the second light emitting element OLED2 may include the first hole control layer HTR1, a first-second light emitting layer EML1-2, and the first electron control layer ETR1. The second light emitting stack ST2 of the second light emitting element OLED2 may include the second hole control layer HTR2, a second-second light emitting layer EML2-2, and the second electron control layer ETR2.

According to an embodiment, the first-first light emitting layer EML1-1 and the first-second light emitting layer EML1-2 may emit lights having different wavelengths. As an example, the first-first light emitting layer EML1-1 may emit the green light, and the first-second light emitting layer EML1-2 may emit the blue light. For example, the second-first light emitting layer EML2-1 and the second-second light emitting layer EML2-2 may also emit lights having different wavelengths. As an example, the second-first light emitting layer EML2-1 may emit the green light, and the second-second light emitting layer EML2-2 may emit the blue light.

Referring to FIG. 5C, the first light emitting stack ST1 may include the first light emitting layer EML1, the first hole control layer HTR1, and the first electron control layer ETR1, and the first light emitting layer EML1 may be disposed between the first hole control layer HTR1 and the first electron control layer ETR1.

The first hole control layer HTR1 may include at least one of a first hole injection layer and a first hole transport layer. The first hole control layer HTR1 may further include at least one of a first hole buffer layer and a first electron block layer.

The first electron control layer ETR1 may include at least one of a first electron injection layer and a first electron transport layer. The first electron control layer ETR1 may further include a first hole block layer.

The second light emitting stack ST2 may include the second light emitting layer EML2, the second hole control layer HTR2, and the second electron control layer ETR2. The second light emitting layer EML2 may be disposed between the second hole control layer HTR2 and the second electron control layer ETR2.

The second hole control layer HTR2 may include at least one of a second hole injection layer and a second hole transport layer. The second electron control layer ETR2 may include at least one of a second electron injection layer and a second electron transport layer. Descriptions on the first hole control layer HTR1 and the first electron control layer ETR1 may be equally applied to the second hole control layer HTR2 and the second electron control layer ETR2.

According to the embodiment, each of the first electrode AE, the first light emitting layer EML1, and the second light emitting layer EML2 may be patterned using a mask and may be formed separately for each pixel. For example, the first and second hole control layers HTR1 and HTR2, the first and second electron control layers ETR1 and ETR2, the charge generation layer CGL, and the second electrode CE may be commonly formed over the pixels using an open mask. For example, each of the first and second hole control layers HTR1 and HTR2, the first and second electron control layers ETR1 and ETR2, the charge generation layer CGL, and the second electrode CE may have a single integrated shape. However, the disclosure should not be limited thereto or thereby, and at least one of the first and second hole control layers HTR1 and HTR2 and the first and second electron control layers ETR1 and ETR2 may be formed separately for each pixel using a mask.

FIG. 5C shows the structure in which the light emitting element OLED includes two light emitting stacks ST1 and ST2 and one charge generation layer CGL disposed between the light emitting stacks ST1 and ST2 as a representative example, however, the disclosure should not be limited thereto or thereby. According to an embodiment, the light emitting element OLED may include three, four, or more light emitting stacks.

However, the disclosure should not be limited thereto or thereby, and the above descriptions may be applied to the light emitting element OLED corresponding to each of the light emitting areas PXA-G, PXA-B, and PXA-R.

Referring again to FIGS. 5B and 6, the shape of the first valley pattern VP1 when viewed in the cross-section is shown. In the following descriptions, the first valley pattern VP1 may be referred to as a valley pattern, and an inclination angle and a depth of the first valley pattern VP1 will be described as a representative example, however, descriptions on the first valley pattern VP1 may also be applied to the second valley pattern VP2 and the third valley pattern VP3.

As shown in FIG. 5B, the first valley pattern VP1 may include a first-first side surface SS1-1 closer to the first light emitting opening OP1 than the second light emitting opening OP2, a first-second side surface SS1-2 closer to the second light emitting opening OP2 than the first-first side surface SS1-1 adjacent to the second light emitting opening OP2, and a lower surface DS1 disposed between the first-first side surface SS1-1 and the first-second side surface SS1-2. For example, the first valley pattern VP1 may include the first-first side surface SS1-1 closer to the first light emitting area PXA-G than the second light emitting area PXA-B and the first-second side surface SS1-2 closer to the second light emitting area PXA-B than the first-first side surface SS1-1 adjacent to the second light emitting area PXA-B.

A distance d2 from a boundary between the first electrode AE and the first light emitting opening OP1 to the first-second side surface SS1-2 may be greater than a distance d1 from the boundary between the first electrode AE and the first light emitting opening OP1 to the first-first side surface SS1-1. For example, the first-second side surface SS1-2, which has a relatively large inclination angle, may be positioned farther away from the first light emitting area PXA-G by a certain distance.

According to an embodiment, the distance d2 from the boundary between the first electrode AE and the first light emitting opening OP1 to the first-second side surface SS1-2 may be substantially greater than or equal to about 8 □. As shown in FIG. 5B, a thickness of the light emitting stacks ST1 and ST2 and the charge generation layer CGL, which are disposed on the first-second side surface SS1-2, may become thinner, and thus, a resistance of the light emitting stacks ST1 and ST2 and the charge generation layer CGL may increase. For example, portions with higher resistance may be positioned farther away from the first light emitting opening OP1 by a certain distance to reduce electrical noise and improve power efficiency.

As shown in FIG. 6, the side surfaces SS1-1 and SS1-2 of the first valley pattern VP1 with the recessed shape may be inclined at a selected angle with respect to the lower surface DS1. An inclination angle θ1 of the first-first side surface SS1-1 inclined with respect to an imaginary extension line of the lower surface may be smaller than an inclination angle θ2 of the first-second side surface SS1-2. As an example, the inclination angle θ1 of the first-first side surface SS1-1 may be greater than or equal to about zero (0) degree and smaller than about 74 degrees, and the inclination angle θ2 of the first-second side surface SS1-2 may be greater than or equal to about 74 degrees and smaller than or equal to about 90 degrees.

In case that the inclination angle θ1 of the first-first side surface SS1-1 is smaller than about 74 degrees, the thickness of the charge generation layer CGL disposed on the first-first side surface SS1-1 may be more uniform, and thus, the accumulation of excess charge may be eliminated. For example, a distribution of charges in the area adjacent to the first light emitting area PXA-G may be kept constant, and a path through which the charges move may be stably secured, thereby preventing excessive charge accumulation on the inclined surface. Accordingly, an overshoot phenomenon caused by the excess charges may be suppressed, and the luminance corresponding to a grayscale value may be provided, thereby improving image quality characteristics.

In case that the inclination angle θ2 of the first-second side surface SS1-2 is greater than or equal to about 74 degrees, the thickness of the charge generation layer CGL disposed on the first-second side surface SS1-2 may become thinner, and thus, the lateral leakage current between the first light emitting area PXA-G and the second light emitting area PXA-B may be reduced. For example, as the lateral leakage current is reduced, the accuracy of luminance control for each pixel may increase, and thus, the occurrence of gray-crushing defects, where the luminance decreases compared to a white light in case that only one pixel emits light, may be reduced.

According to an embodiment, the first valley pattern VP1 may have a depth h greater than or equal to about 100 nm and smaller than or equal to about 650 nm. The depth of the first valley pattern VP1 may indicate a depth recessed from the upper surface the pixel definition layer PDL. In case that the depth h of the first valley pattern VP1 is smaller than about 100 nm, the reduction in the thickness of the charge generation layer CGL disposed on the pixel definition layer PDL may decrease, thereby reducing the effectiveness of preventing the lateral leakage current. Conversely, in case that the depth h of the first valley pattern VP1 is greater than about 650 nm, the charge generation layer CGL disposed on the pixel definition layer PDL may be physically damaged, and the electrical reliability may be reduced.

As shown in FIG. 6, an organic layer OL may refer to a common layer including the first and second hole control layers HTR1 and HTR2, the first and second electron control layers ETR1 and ETR2, and the charge generation layer CGL, which are commonly disposed on the first electrode AE. The organic layer OL and the second electrode CE according to the disclosure may be disposed on the upper surface of the pixel definition layer PDL and inside the first valley pattern VP1. The organic layer OL and the second electrode CE may be formed as the common layer having an integrated shape on the first electrode AE as described above.

A thickness TH1 of the organic layer OL on the first-first side surface SS1-1 of the first valley pattern VP1 may be different from a thickness TH2 of the organic layer OL on the first-second side surface SS1-2 of the first valley pattern VP1. As described above, the inclination angle θ1 of the first-first side surface SS1-1 may be smaller than the inclination angle θ2 of the first-second side surface SS1-2. Accordingly, the thickness TH1 of the organic layer OL on the first-first side surface SS1-1 may be greater than the thickness TH2 of the organic layer OL on the first-second side surface SS1-2. For example, a thickness of the charge generation layer CGL overlapping the first-first side surface SS1-1 of the first valley pattern VP1 may be greater than a thickness of the charge generation layer CGL overlapping the first-second side surface SS1-2 of the first valley pattern VP1.

According to an embodiment, the thickness TH2 of the organic layer OL on the first-second side surface SS1-2 of the first valley pattern VP1 may be smaller than or equal to about 80 nm. The thickness TH2 of the organic layer OL on the first-second side surface SS1-2 of the first valley pattern VP1 may be thin compared to the thickness TH1 of the organic layer OL on the first-first side surface SS1-1, and thus, the resistance of the organic layer OL may increase. For example, the lateral leakage current may flow through the first and second hole control layers HTR1 and HTR2 and/or the charge generation layer CGL. However, as the resistance of the first and second hole control layers HTR1 and HTR2 and/or the charge generation layer CGL increases, the leakage of the current may be prevented. For example, the n-type charge generation layer n-CGL of the charge generation layer CGL may be disconnected on the first-second side surface SS1-2, and thus, the lateral leakage current between adjacent pixels may be further suppressed.

Referring again to FIG. 5B, the second valley pattern VP2 may include a second-first side surface SS2-1 closer to the second light emitting opening OP2 than the first light emitting opening OP1, a second-second side surface SS2-2 closer to the first light emitting opening OP1 than the second-first side surface SS2-1 adjacent to the first light emitting opening OP1, and a lower surface DS2 disposed between the second-first side surface SS2-1 and the second-second side surface SS2-2. Similar to the first valley pattern VP1, an inclination angle of the second-first side surface SS2-1 may be smaller than an inclination angle of the second-second side surface SS2-2, and the above descriptions on the inclination angle, depth, and thickness of the first valley pattern VP1 may be equally applied to the second valley pattern VP2.

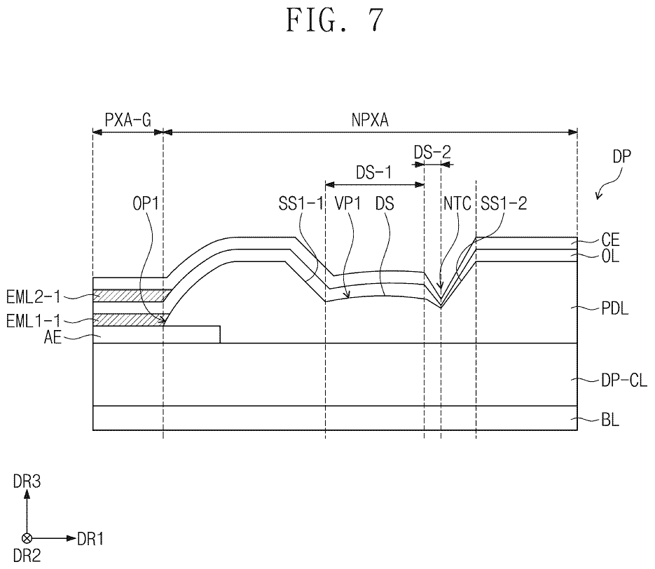

FIGS. 7, 8, 9A, and 9B are enlarged schematic cross-sectional views of portions of display panels according to embodiments. In FIGS. 7, 8, 9A, and 9B, the same/similar reference numerals denote the same/similar reference numerals in FIGS. 1 to 6, and thus, detailed descriptions of the same/similar reference numerals will be omitted.

Referring to FIG. 7, an organic layer OL may include a first electron control layer ETR1 (refer to FIG. 6), a charge generation layer CGL (refer to FIG. 6), and a second hole control layer HTR2 (refer to FIG. 6). For example, the organic layer OL may include a first hole control layer HTR1 (refer to FIG. 6) and a second electron control layer ETR2 (refer to FIG. 6). For example, the organic layer OL may refer to a common layer having a single integrated shape.

As shown in FIG. 7, a lower surface DS1 of a first valley pattern VP1 may include a first area DS-1 and a second area DS-2. The second area DS-2 may be disposed between the first area DS-1 and a first-second side surface SS1-2 and may be recessed deeper than the first area DS-1. A portion that is deeply recessed between the second area DS-2 and the first-second side surface SS1-2 may be defined as a notch NTC. As the notch NTC is formed, a thickness of the organic layer OL disposed on the second area DS-2 and the first-second side surface SS1-2 may become thinner, or the organic layer OL may be partially disconnected according to an inclination angle. Accordingly, a resistance of the organic layer OL on the first-second side surface SS1-2 may increase, and a lateral leakage current may be reduced.

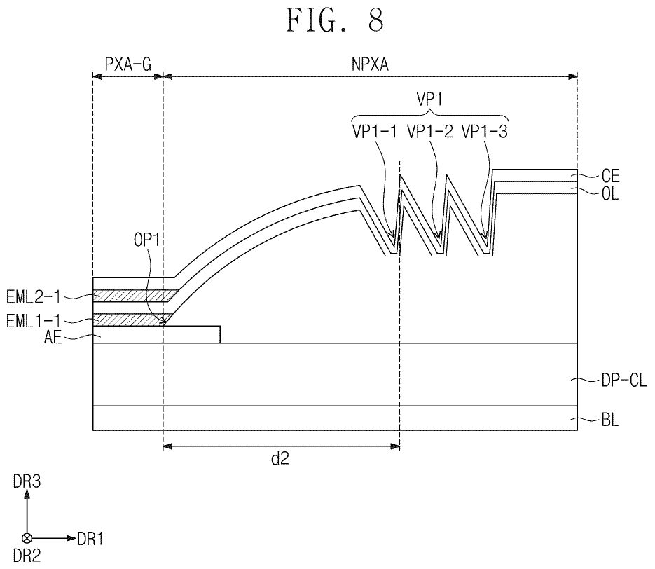

Referring to FIG. 8, a first valley pattern VP1 may include a first-first valley pattern VP1-1, a first-second valley pattern VP1-2, and a first-third valley pattern VP1-3. For example, the first valley pattern VP1 may not consist of only a single valley pattern but may include multiple patterns arranged sequentially from a first light-emitting opening OP1 toward the first direction DR1. According to an embodiment, a distance from a boundary between a first electrode AE and the first light emitting opening OP1 to the first-first valley pattern VP1-1 may be greater than or equal to about 8 □.

FIG. 8 shows three valley patterns, however, the number of the valley patterns should not be limited to three as shown in FIG. 8. As an example, n valley patterns including first valley pattern closest to the first light emitting opening OP1 to n-th valley pattern and consecutively arranged toward a second light emitting opening OP2 (refer to FIG. 5B) may be arranged. Here, n may be an integer greater than 1.

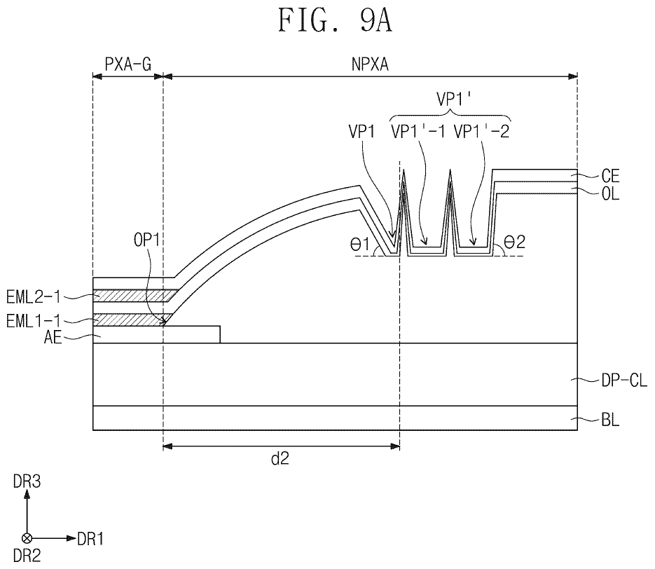

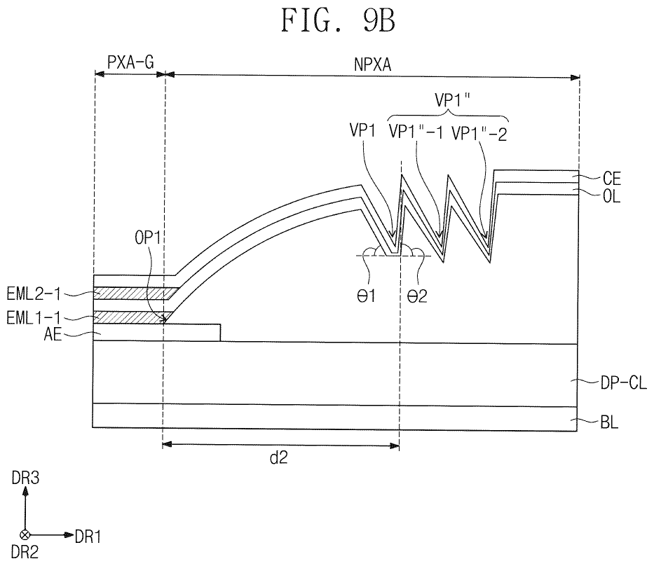

Referring to FIG. 9A, a valley pattern may include a first valley pattern VP1 and may further include an additional valley pattern VP1′ consecutively arranged along the first direction DR1. The additional valley pattern VP1′ may include a first additional valley pattern VP1′-1 and a second additional valley pattern VP1′-2. FIG. 9A shows two valley patterns as the additional valley pattern VP1′, however, the number of additional valley patterns should not be limited to that shown in FIG. 9A.

Inner side surfaces of the additional valley pattern VP1′ may have the same inclination angle θ2 as the inclination angle θ2 of the first-second side surface (refer to SS1-2 of FIG. 6) of the first valley pattern VP1. Accordingly, a thickness of an organic layer OL disposed on the inner side surfaces of the additional valley pattern VP1′ may be thinner than the thickness of the organic layer OL disposed on the first-first side surface SS1-1 (refer to FIG. 6) of the first valley pattern VP1.

According to an embodiment, a distance from a boundary between a first electrode AE and a first light emitting opening OP1 to the additional valley pattern VP1′ may be greater than or equal to about 8 □. For example, the additional valley pattern VP1′ including the inner side surfaces with the large inclination angle θ2 may be positioned to ensure a sufficient effective distance from the first light emitting opening OP1. Accordingly, although the thickness of the organic layer OL disposed on the inner side surfaces of the additional valley pattern VP1′ decreases, a path through which charges move may be secured sufficiently, and thus, the accumulation of the excess charges on the inclined surface may be prevented. For example, due to the inclination of the additional valley pattern VP1′, the lateral leakage current phenomenon may be prevented from occurring between adjacent light emitting areas.

Referring to FIG. 9B, a valley pattern may include a first valley pattern VP1 and may further include an additional valley pattern VP1″ consecutively arranged along the first direction DR1. The additional valley pattern VP1″ may include a first additional valley pattern VP1″-1 and a second additional valley pattern VP1″-2. FIG. 9B shows two valley patterns as the additional valley pattern VP1″, however, the number of additional valley patterns should not be limited to that shown in FIG. 9B.

The additional valley pattern VP1″ may have substantially the same structure as the first valley pattern VP1 except that the additional valley pattern VP1″ does not include the lower surface (refer to DS1 of FIG. 6). For example, the additional valley pattern VP1″ may have a shape in which a first-first side surface (refer to SS1-1 of FIG. 6) of the first valley pattern VP1 is directly connected to a first-second side surface (refer to SS1-2 of FIG. 6). A side surface of the additional valley pattern VP1″ may have the same inclination angle θ1 as the inclination angle θ1 of the first-first side surface (refer to SS1-1 of FIG. 6), and another side surface of the additional valley pattern VP1″ may have the same inclination angle θ2 as the inclination angle θ2 of the first-second side surface (refer to SS1-2 of FIG. 6). Accordingly, a thickness of an organic layer OL disposed on the other side surface of the additional valley pattern VP1″ may be smaller than a thickness of the organic layer OL disposed in a first light emitting opening OP1.

Similar to FIG. 9A, a distance from a boundary between a first electrode AE and the first light emitting opening OP1 to the additional valley pattern VP1″ may be greater than or equal to about 8 □. Accordingly, the additional valley pattern VP″ including the other side surfaces with the large inclination angle θ2 may be positioned to ensure a sufficient effective distance from the first light emitting opening OP1. Accordingly, the lateral leakage current phenomenon may be prevented from occurring between adjacent light emitting areas. As a result, a charge imbalance in an area adjacent to a first light emitting area PXA-G may be resolved, and the lateral leakage current phenomenon may be prevented from occurring between adjacent light emitting areas.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display panel comprising:
a base layer;
a pixel definition layer disposed on the base layer and comprising a first light emitting opening and a second light emitting opening; and
a light emitting element layer comprising:
a first light emitting element overlapping the first light emitting opening, and
a second light emitting element overlapping the second light emitting opening, wherein
the pixel definition layer comprises a valley pattern disposed between the first light emitting opening and the second light emitting opening and recessed from an upper surface of the pixel definition layer in a thickness direction of the pixel definition layer, the valley pattern comprising a first valley pattern disposed between the first light emitting opening and the second light emitting opening and disposed closer to the first light emitting opening than the second light emitting opening, the first valley pattern comprising:
a first-first side surface;
a first-second side surface disposed closer to the second light emitting opening than the first-first side surface; and
a lower surface disposed between the first-first side surface and the first-second side surface, and
the first-first side surface has an inclination angle smaller than an inclination angle of the first-second side surface.

2. The display panel of claim 1, wherein
the inclination angle of the first-first side surface is smaller than about 74 degrees, and
the inclination angle of the first-second side surface is greater than or equal to about 74 degrees and smaller than or equal to about 90 degrees.

3. The display panel of claim 1, wherein
the first light emitting element comprises a first electrode partially exposed through the first light emitting opening, and
a distance from a boundary between the first electrode and the first light emitting opening to the first-second side surface is greater than or equal to about 8 micrometers.

4. The display panel of claim 1, wherein the first valley pattern has a depth smaller than or equal to about 650 nm.

5. The display panel of claim 1, wherein
the valley pattern further comprises a second valley pattern disposed between the first light emitting opening and the second light emitting opening and disposed closer the second light emitting opening than the first light emitting opening,
the second valley pattern comprises:
a second-first side surface;
a second-second side surface disposed closer to the first light emitting opening than the second-first side surface; and
a lower surface disposed between the second-first side surface and the second-second side surface, and
the second-first side surface has an inclination angle smaller than an inclination angle of the second-second side surface.

6. The display panel of claim 5, wherein
the first valley pattern comprises a first-first valley pattern and a first-second valley pattern, which are arranged to surround a portion of the first light emitting opening, and
an area where the first-first valley pattern is spaced apart from the first-second valley pattern faces the second valley pattern.

7. The display panel of claim 1, wherein the first light emitting element comprises:
a first electrode partially exposed through the first light emitting opening;
a first-first light emitting layer disposed on the first electrode;
a charge generation layer disposed on the first-first light emitting layer;
a second-first light emitting layer overlapping the first-first light emitting layer and disposed on the charge generation layer; and
a second electrode disposed on the second-first light emitting layer and the charge generation layer.

8. The display panel of claim 7, wherein the first-first light emitting layer and the second-first light emitting layer emit lights having a same wavelength.

9. The display panel of claim 7, wherein
the second light emitting element comprises:
a first electrode partially exposed through the second light emitting opening;
a first-second light emitting layer disposed on the first electrode of the second light emitting element;
the charge generation layer disposed on the first-second light emitting layer;
a second-second light emitting layer overlapping the first-second light emitting layer and disposed on the charge generation layer; and
the second electrode disposed on the second-second light emitting layer and the charge generation layer,
the charge generation layer of the first light emitting element and the charge generation layer of the second light emitting element have a single integrated shape, and
the second electrode of the first light emitting element and the second electrode of the second light emitting element have a single integrated shape.

10. The display panel of claim 9, wherein
the first-first light emitting layer and the second-first light emitting layer emit lights having a same wavelength, and
the first-first light emitting layer and the first-second light emitting layer emit lights having different wavelengths from each other.

11. The display panel of claim 9, wherein
the charge generation layer overlaps the valley pattern,
the charge generation layer comprises an n-type charge generation layer and a p-type charge generation layer disposed on the n-type charge generation layer, and
the n-type charge generation layer is disconnected on the first-second side surface of the first valley pattern.

12. The display panel of claim 9, wherein a portion of the charge generation layer, which overlaps the first-first side surface of the first valley pattern, has a thickness greater than a thickness of a portion of the charge generation layer, which overlaps the first-second side surface of the first valley pattern.

13. The display panel of claim 1, wherein the lower surface of the first valley pattern comprises;
a first area; and
a second area disposed between the first area and the first-second side surface and recessed deeper than the first area.

14. The display panel of claim 1, wherein
the first valley pattern comprises first to n-th valley patterns, where n is an integer greater than 1, and
the first to n-th valley patterns are consecutively arranged from the first light emitting opening toward the second light emitting opening.

15. The display panel of claim 14, wherein
the first light emitting element comprises a first electrode partially exposed through the first light emitting opening, and
a distance from a boundary between the first electrode and the first light emitting opening to the first valley pattern is greater than or equal to about 8 micrometers.

16. A display panel comprising:
a base layer comprising a first light emitting area, a second light emitting area adjacent to the first light emitting area, and a non-light-emitting area adjacent to the first light emitting area and the second light emitting area;
a pixel definition layer disposed on the base layer and comprising first and second light emitting openings to respectively overlap the first and second light emitting areas; and
a light emitting element layer, at least a portion of which is disposed in the first and second light emitting openings, wherein
the pixel definition layer comprises a valley pattern overlapping the non-light-emitting area and recessed from an upper surface of the pixel definition layer in a thickness direction of the pixel definition layer, the valley pattern comprising:
a first valley pattern disposed closer to the first light emitting opening than the second light emitting opening, and
a second valley pattern disposed closer to the second light emitting opening than the first light emitting opening, and
the first valley pattern comprises:
a first-first side surface surrounding a portion of the first light emitting area;
a first-second side surface disposed closer to the second light emitting opening than the first-first side surface ; and
a lower surface disposed between the first-first side surface and the first-second side surface, and
the first-first side surface has an inclination angle smaller than an inclination angle of the first-second side surface.

17. The display panel of claim 16, wherein the light emitting element layer comprises:
a first anode partially exposed through the first light emitting opening;
a second anode partially exposed through the second light emitting opening;
a first-first light emitting layer disposed on the first anode;
a first-second light emitting layer disposed on the second anode;
an organic layer commonly disposed on the first anode and the second anode;
a second-first light emitting layer disposed on the first-first light emitting layer;
a second-second light emitting layer disposed on the first-second light emitting layer; and
a cathode commonly disposed on the second-first light emitting layer and the second-second light emitting layer.

18. The display panel of claim 17, wherein
each of the first-first light emitting layer and the second-first light emitting layer emits a first light, and
each of the first-second light emitting layer and the second-second light emitting layer emits a second light having a wavelength different from a wavelength of the first light.

19. The display panel of claim 17, wherein a thickness of the organic layer on the first-first side surface is greater than a thickness of the organic layer on the first-second side surface.

20. An electronic apparatus comprising:
a display module;
a window disposed on the display module; and
an external case disposed under the display module, the display module comprising:
a base layer;
a pixel definition layer disposed on the base layer and comprising a first light emitting opening and a second light emitting opening; and
a light emitting element layer comprising a first light emitting element overlapping the first light emitting opening and a second light emitting element overlapping the second light emitting opening,
wherein the pixel definition layer comprises a valley pattern disposed between the first light emitting opening and the second light emitting opening and recessed from an upper surface of the pixel definition layer in a thickness direction of the pixel definition layer, the valley pattern comprising a first valley pattern disposed between the first light emitting opening and the second light emitting opening and disposed closer to the first light emitting opening than the second light emitting opening, the first valley pattern comprising:
a first-first side surface;
a first-second side surface disposed closer to the second light emitting opening than the first-first side surface, and
a lower surface disposed between the first-first side surface and the first-second side surface,
wherein the first-first side surface has an inclination angle smaller than an inclination angle of the first-second side surface.
